(19) United States
(12) Patent Application Publication
(10) Pub. No.: US 2009/0200553 A1
(43) Pub. Date: Aug. 13, 2009

(54) HIGH TEMPERATURE THIN FILM TRANSISTOR ON SODA LIME GLASS

(75) Inventors: Ya-Tang Yang, Cupertino, CA (US); Beom Soo Park, San Jose, CA (US); Tae K. Won, San Jose, CA (US); Soo Young Choi, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC, Santa Clara, CA (US)

(21) Appl. No.: 12/413,136

(22) Filed: Mar. 27, 2009

Related U.S. Application Data
(63) Continuation-in-part of application No. 12/277,921, filed on Nov. 25, 2008.
(60) Provisional application No. 60/991,685, filed on Nov. 30, 2007.

(51) Int. Cl. H01L 29/786; B32B 17/06; H01L 21/336

(52) U.S. Cl. 257/57; 428/428; 428/336; 438/158; 257/632; 257/E29.273; 257/E21.414

(57) ABSTRACT

The present invention generally comprises a low cost TFT and a method of manufacturing a TFT. For TFTs, soda lime glass would be an attractive alternative to non-alkali glass, but a soda lime glass substrate will permit sodium to diffuse into the active layer and degrade the performance of the TFT. Substrates comprising a polyimide, because they are flexible, would also be attractive to utilize instead of non-alkali glass substrates, but the plastic substrates permit carbon to diffuse into the active layer. By depositing a silicon oxynitride adhesion layer over the soda lime glass substrate and a silicon rich barrier layer over the adhesion layer, diffusion may be reduced and deposition may occur at high temperatures. Thus, a lower cost TFT may be produced with a soda lime glass substrate or a substrate comprising a polyimide as compared to a non-alkali glass substrate.

### CROSS-REFERENCE TO RELATED APPLICATIONS

This application is a Continuation-in-Part of U.S. patent application Ser. No. 12/277,921 (APPM/12656), filed Nov. 25, 2008, which application claims benefit of U.S. Provisional Patent Application Ser. No. 60/991,685 (APPM/12656L), filed Nov. 30, 2007, both of which are herein incorporated by reference.

### BACKGROUND OF THE INVENTION

1. Field of the Invention

Embodiments of the present invention generally relate to a thin film transistor (TFT) formed over either a soda lime glass substrate or a polyimide containing substrate.

2. Description of the Related Art

Liquid crystal displays (LCDs) may be formed on high performance non-alkali glass developed specifically for LCD applications. The LCD comprises a TFT formed over a non-alkali glass substrate. Non-alkali glass substrates have few contaminants that may diffuse into the TFT and thus make non-alkali glass substrates attractive for TFT fabrication. However, non-alkali glass is quite expensive. Soda lime glass has been proposed as an alternative to non-alkali glass substrates, but soda lime glass has a significant amount of sodium that easily diffuses into the active layer of the TFT which will degrade the TFT device.

Therefore, there is a need in the art for a TFT formed on a substrate that is lower in cost than non-alkali-glass substrates. There is also a need in the art for the TFT formed on the lower cost substrate to not have contaminants diffuse into the active layer from the substrate.

### SUMMARY OF THE INVENTION

The present invention generally comprises a low cost TFT and a method for making the TFT. In one embodiment, a semiconductor device includes a soda lime glass substrate, a silicon oxynitride adhesion layer disposed over the soda lime glass substrate and a silicon rich silicon nitride barrier layer disposed over the adhesion layer. The barrier layer has a SiH bond density percentage between about 15 percent to about 25 percent and a reflective index between about 1.80 and about 1.95.

In another embodiment, a semiconductor device formation method includes depositing a silicon oxynitride adhesion layer on a soda lime glass substrate and depositing a silicon rich silicon nitride barrier layer on the adhesion layer. The barrier layer has a SiH bond density percentage between about 15 percent to about 25 percent and a reflective index between about 1.80 and about 1.95.

In another embodiment, a thin film transistor formation thin film transistor formation method is disclosed. The method includes depositing an adhesion layer on a soda lime glass substrate and depositing a silicon rich silicon nitride barrier layer over the adhesion layer. The barrier layer has a SiH bond density percentage between about 15 percent to about 25 percent and a reflective index between about 1.80 and about 1.95. The method also includes depositing a metal gate layer over the barrier layer, depositing a gate dielectric layer over the metal gate layer, and depositing an active layer over the gate dielectric layer. The method also includes depositing a source-drain region over the active layer and depositing a passivation layer over the source-drain region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PECVD apparatus according to one embodiment of the invention.

FIG. 2 is a schematic drawing of a TFT structure.

FIG. 3 is a cross sectional view of a thin film transistor according to one embodiment.

FIG. 4 is a graph showing the level of sodium diffusion to an active layer and gate dielectric layer from a substrate according to one embodiment.

FIG. 5 is a graph showing the level of sodium diffusion to an active layer and gate dielectric layer from a substrate according to one embodiment.

FIG. 6 is a graph showing the level of sodium diffusion to an active layer and gate dielectric layer from a substrate according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a low cost TFT and a method of manufacturing a TFT. For TFTs, soda lime glass would be an attractive alternative to non-alkali glass, but a soda lime glass substrate will permit sodium to diffuse into the active layer and degrade the performance of the TFT. Substrates comprising a polyimide, because they are flexible, would also be attractive to utilize instead of non-alkali glass substrates, but the plastic substrates permit carbon to diffuse into the active layer. By depositing a silicon rich barrier layer having a SiH bond density percentage between about 15 percent to about 25 percent and a reflective index between about 1.80 and about 1.95 over the soda lime glass substrate or substrate comprising a polyimide, both sodium and carbon diffusion may be reduced. Thus, a lower cost TFT may be produced with a soda lime glass substrate or a substrate comprising a polyimide as compared to a non-alkali glass substrate.

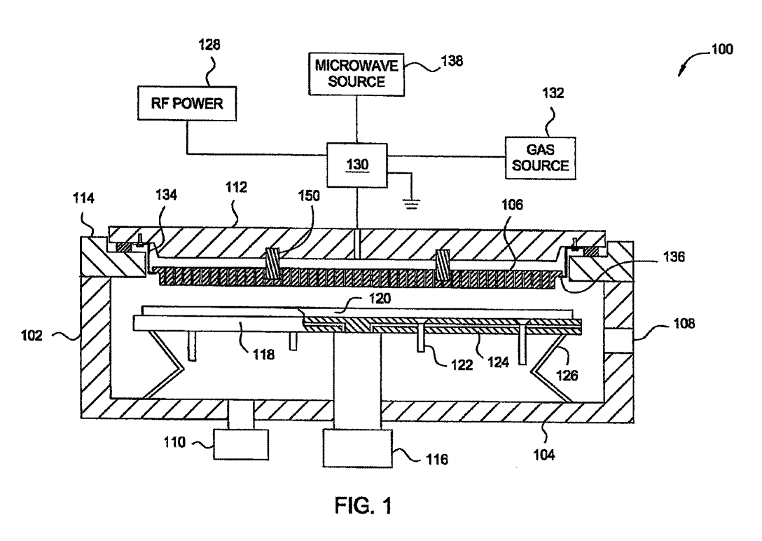

FIG. 1 is a cross sectional view of a PECVD apparatus according to one embodiment of the invention. The apparatus includes a chamber 100 in which one or more films may be deposited onto a substrate 120. One suitable PECVD apparatus which may be used is available from AKT America, Inc., a subsidiary of Applied Materials, Inc., located in Santa Clara, Calif. While the description below will be made in reference to a PECVD apparatus, it is to be understood that the invention is equally applicable to other processing chambers as well, including those made by other manufacturers.

The chamber 100 generally includes walls 102, a bottom 104, a showerhead 106, and susceptor 118 which define a process volume. The process volume is accessed through a slit valve opening 108 such that the substrate 120 may be transferred in and out of the chamber 100. The susceptor 118 may be coupled to an actuator 116 to raise and lower the susceptor 118. Lift pins 122 are moveably disposed through the susceptor 118 to support a substrate 120 prior to placement onto the susceptor 118 and after removal from the susceptor 118. The susceptor 118 may also include heating and/or cooling elements 124 to maintain the susceptor 118 at a desired temperature. The susceptor 118 may also include grounding straps 126 to provide RF grounding at the periphery of the susceptor 118.

The showerhead 106 is coupled to a backing plate 112 by a fastening mechanism 150. The showerhead 106 may be coupled to the backing plate 112 by one or more coupling supports 150 to help prevent sag and/or control the straightness/curvature of the showerhead 106. In one embodiment, twelve coupling supports 150 may be used to couple the showerhead 106 to the backing plate 112. The coupling supports 150 may include a fastening mechanism such as a nut and bolt assembly. In one embodiment, the nut and bolt assembly may be made with an electrically insulating material. In another embodiment, the bolt may be made of a metal and surrounded by an electrically insulating material. In still another embodiment, the showerhead 106 may be threaded to receive the bolt. In yet another embodiment, the nut may be formed of an electrically insulating material. The electrically insulating material helps to prevent the coupling supports 150 from becoming electrically coupled to any plasma that may be present in the chamber 100. Additionally and/or alternatively, a center coupling mechanism may be present to couple the backing plate 112 to the showerhead 106. The center coupling mechanism may surround a backing plate support ring (not shown) and be suspended from a bridge assembly (not shown). The showerhead 106 may additionally be coupled to the backing plate 112 by a bracket 134. The bracket 134 may have a ledge 136 upon which the showerhead 106 may rest. The backing plate 112 may rest on a ledge 114 coupled with the chamber walls 102 to seal the chamber 100.

A gas source 132 is coupled to the backing plate 112 to provide both processing gas and cleaning gas through gas passages in the showerhead 106 to the substrate 120. The processing gases travel through a remote plasma source/RF choke unit 130. A vacuum pump 110 is coupled to the chamber 100 at a location below the susceptor 118 to maintain the process volume 106 at a predetermined pressure. A RF power source 128 is coupled to the backing plate 112 and/or to the showerhead 106 to provide a RF current to the showerhead 106. The RF current creates an electric field between the showerhead 106 and the susceptor 118 so that a plasma may be generated from the gases between the showerhead 106 and the susceptor 118. Various frequencies may be used, such as a frequency between about 0.3 MHz and about 200 MHz. In one embodiment, the RF current is provided at a frequency of 13.56 MHz.

Between processing substrates, a cleaning gas may be provided to the remote plasma source/RF choke unit 130 so that a remote plasma is generated and provided to clean the chamber 100 components. A microwave current from a microwave source 138 coupled to the remote plasma source/RF choke 130 may ignite the plasma. It is to be understood that sources other than microwave sources may be used. Additionally, while the remote plasma source/RF choke 130 is shown coupled to ground, it is to be understood that the RF current returns to the source driving it which is sometimes referred to as “RF grounding” in the art. The cleaning gas may be further excited by the RF power source 128 provided to the showerhead 106. Suitable cleaning gases include by are not limited to NF₃, F₂, and SF₆. The spacing between the top surface of the substrate 120 and the showerhead 106 may be between about 400 mil and about 1,200 mil. In one embodiment, the spacing may be between about 400 mil and about 800 mil.

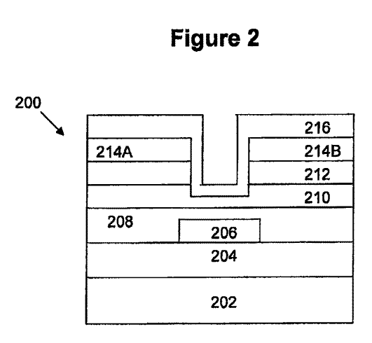

PECVD may be used to deposit various layers of a TFT. FIG. 2 is a schematic drawing of a TFT structure 200 according to one embodiment of the invention. The TFT structure comprises a substrate 202. In one embodiment, the substrate may comprise soda lime glass. In another embodiment, the substrate may comprise a plastic. In one embodiment, the plastic may be a polyimide. In another embodiment, the substrate may comprise poly(4,4′-oxydiphenylene-pyromellitimide).

When the substrate is soda lime glass, sodium, magnesium, calcium, and carbon may be present and diffuse into the active layer of the TFT. When the substrate is a plastic substrate, carbon, sodium, and calcium may be present and diffuse into the active layer of the TFT. The contaminants may degrade the TFT device performance or even cause the device to fail. To prevent diffusion of the contaminants into the active layer, a barrier layer 204 may be deposited over the substrate. The barrier layer 204 may comprise silicon nitride, a silicon oxynitride, silicon carbide, or silicon dioxide. Of course, multiple barrier layers 204 may be present in which a combination of the aforementioned barrier layers 204 are stacked over the substrate. Over the barrier layer 204, the metal gate 206, gate dielectric layer 208, active layer 210, doped active layer 212, source-drain region 214A, 214B, and passivation layer 216 may be deposited.

The barrier layer 204 may be deposited by introducing a substrate into a PECVD processing chamber and disposing the substrate onto a susceptor. The susceptor may be maintained at a temperature between about 180 degrees Celsius and about 210 degrees Celsius. For silicon nitride, a silicon precursor processing gas, a nitrogen precursor processing gas, nitrogen gas, and hydrogen gas may be introduced into the processing chamber. In one embodiment, the silicon precursor gas may comprise silane. In one embodiment, the nitrogen precursor gas may comprise ammonia.

The barrier layer 204 should be a silicon rich layer. By silicon rich it is to be understood to include more silicon is present than is necessary to produce hydrogenated silicon nitride SiN:H. Silicon rich hydrogenated silicon nitride films have a higher silicon content then standard hydrogenated silicon nitride films. The barrier layer 204 may be deposited to a thickness between about 50 Angstroms to about 10000 Angstroms. In one embodiment, the barrier layer 204 thickness may be between about 100 Angstroms to about 500 Angstroms. In another embodiment, the barrier layer 204 thickness may be between about 250 Angstroms to about 400 Angstroms. In another embodiment, the barrier layer 204 may have a thickness between about 0.9 microns and about 1:0.1 microns.

While discussed as a single barrier layer 204, a multi-layer barrier layer may be used. In situations where the barrier layer may be uneven when deposited, a second barrier layer may be deposited over the first barrier layer. The first barrier layer may be deposited to increase adhesion with the substrate 202. The first barrier layer may have a thickness of between about 0.05 to about 0.1 microns. The second barrier layer may then be deposited over the first barrier layer to a thickness between about 0.8 microns to about 1.0 microns. The first barrier layer and the second barrier layer may comprise the same materials. In another embodiment, the first barrier layer and the second barrier layer may comprise a silicon rich hydrogenated silicon nitride. In another embodiment, the first and second barrier layers may be different. For example, the silicon content of the barrier layers may be different.

Over the barrier layer 204, a metal gate layer 206 may be deposited and patterned. In one embodiment, the metal gate layer 206 may comprise chromium. The metal gate layer 206 may be deposited by sputtering. In one embodiment, the metal gate layer 206 may have a thickness between about 1000 Angstroms to about 2000 Angstroms. The metal gate layer 206 may be patterned by photolithography and a plasma etch.

A gate dielectric layer 208 may be deposited over the metal gate layer 206. The gate dielectric layer 208 may be deposited by PECVD. In one embodiment, the gate dielectric layer 208 may comprise hydrogenated silicon nitride. Over the gate dielectric layer, the active layer 210 may be deposited. In one embodiment, the active layer 210 may comprise hydrogenated, amorphous silicon. The active layer 210 may be doped to form a doped active layer 212. In one embodiment, the doped active layer 212 may comprise n-doped hydrogenated, amorphous silicon. In one embodiment, the gate dielectric layer 208, the active layer 210, and the doped active layer 212 may be deposited within the same processing chamber. It is to be understood that while hydrogenated, amorphous silicon has been discussed as the active layer and doped active layer, other materials may be used as well. In particular, transparent conductive oxides such as zinc oxide may be used.

A source drain region may then be formed over the doped active layer 212. A metal layer may be sputter deposited over the doped active layer 212. In one embodiment, the metal layer may comprise chromium. Thereafter, the source drain regions may be formed by a two step photolithography method and plasma etch to define the active channel and source 214A and drain 214B regions of the TFT. A passivation layer 216 may then be deposited. In one embodiment, the passivation layer 216 may comprise silicon nitride.

By utilizing a silicon rich barrier layer over a soda lime glass substrate or a polyimide containing substrate, sodium and carbon diffusion may be reduced. Thus, lower cost substrates may be used without fear of contamination. Therefore, TFTs may be manufactured at a lower cost. No additional layer is present or necessary between the silicon rich barrier layer and the gate dielectric. Additionally, no additional layer is present or necessary between the substrate and the silicon rich barrier layer.

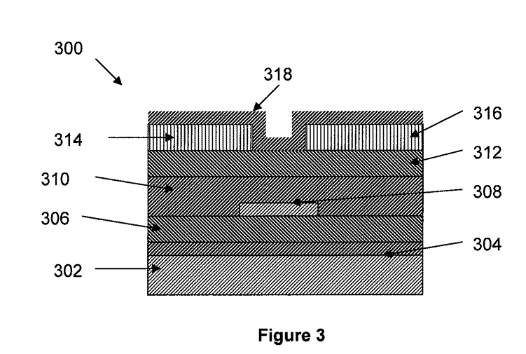

An adhesion layer may also be beneficial when utilizing a substrate comprising soda lime glass or polyimide. FIG. 3 is a cross sectional view of a thin film transistor 300 according to one embodiment. It is to be understood that the embodiments are not limited to thin film transistors, but rather, apply to any semiconductor device formed over soda lime glass substrate or a polyimide substrate.

The thin film transistor 300 includes a substrate 302. In one embodiment, the substrate 302 may comprise soda lime glass. In another embodiment, the substrate 302 may comprise polyimide. Over the substrate 302, an adhesion layer 304 may be deposited. In one embodiment, the adhesion layer 304 may comprise silicon oxynitride. The adhesion layer 304 may be deposited by PECVD where an RF voltage is applied to a showerhead within a processing chamber. The RF voltage may be between about 0.13 W/cm² to about 0.84 W/cm² in one embodiment. During the deposition, a silicon containing gas, an oxygen containing gas, and a nitrogen containing gas may be introduced through the showerhead. In one embodiment, the silicon containing gas may comprise silane. In one embodiment, the silicon containing gas may be introduced at a flow rate of between about 0.028 sccm/cm² to about 0.19 sccm/cm². In one embodiment, the nitrogen containing gas may comprise ammonia. In another embodiment, the nitrogen containing gas may comprise nitrogen gas. In still another embodiment, nitrogen gas may be added along with the silicon containing gas, oxygen containing gas, and nitrogen containing gas. In one embodiment, the flow rate of the nitrogen containing gas may be between about 0.22 sccm/cm² to about 1.50 sccm/cm². In one embodiment, the oxygen containing gas may comprise nitrous oxide. In one embodiment, the oxygen containing gas may be delivered at a flow rate of between about 0.13 sccm/cm² to about 0.84 sccm/cm². The adhesion layer 304 may be deposited at a substrate temperature of between about 60 degrees Celsius to about 250 degrees Celsius and a deposition rate of between about 400 Angstroms per minute and about 4000 Angstroms per minute. The deposition may occur at a pressure of between about 500 mTorr to about 3000 mTorr.

Over the adhesion layer 304, the barrier layer 306 may be deposited. Thereover, the gate electrode 308, gate dielectric layer 310, active layer 312, source electrode 314, drain electrode 316, and passivation layer 318 may be deposited as discussed above. The gate dielectric 310, active layer 312, source electrode 314, and drain electrode 316 may be deposited at a temperature of greater than about 300 degrees Celsius. The passivation layer 318 may be deposited at a temperature of greater than about 290 degrees Celsius. The gate dielectric layer 310 may have a thickness of between about 1000 Angstroms and about 4500 Angstroms. The active layer 312 may have a thickness of between about 500 and about 3000 Angstroms. The barrier layer 306 may have a thickness of between about 50 Angstroms and about 10000 Angstroms.

Table I shows the results of forming a thin film transistor over a soda lime glass substrate. For substrates 1-4, a silicon rich silicon nitride barrier layer was used having a thickness of about 6000 Angstroms. The barrier layer and the adhesion layer were deposited at a substrate temperature of about 200 degrees Celsius. For substrates 1-4, the film stack had a gate dielectric layer of silicon nitride and an active layer of amorphous silicon. The film stack includes the gate dielectric layer and the active layer. For substrates 1 and 3, no adhesion layer was used. For substrates 2 and 4, a 500 Angstrom silicon oxynitride layer was used. For substrates 1 and 2, the film stack was deposited at a substrate temperature of about 200 degrees Celsius and the adhesion was good. For substrates 3 and 4, the film stack was deposited at a substrate temperature of about 345 degrees Celsius. When no adhesion layer was present, the barrier layer and film stack did not adhere well to the substrate. However, when an adhesion layer was present, the barrier layer and film stack adhered well to the substrate.

TABLE I

| | | | Substrate | | Substrate | |
|---|---|---|---|---|---|---|
| | Adhesion | Barrier | Temperature | Film | Temperature | Adhesion |
| Substrate | layer | Layer | (Celsius) | Stack | (Celsius) | Result |
| 1 | None | SiN | 200 | g-SiN/ | 200 | Good |
| | | | | a-Si | | |
| 2 | SiON | SiN | 200 | g-SiN/ | 200 | Good |
| | | | | a-Si | | |
| 3 | None | SiN | 200 | g-SiN/ | 345 | Bad |
| | | | | a-Si | | |
| 4 | SiON | SiN | 200 | g-SiN/ | 345 | Good |
| | | | | a-Si | | |

Table II shows a comparison of the mobility, Vth, Iₒₙ, and I_{off} for a thin film transistor. Substrate 1 is a soda lime glass substrate having a silicon oxynitride adhesion layer and a silicon rich silicon nitride barrier layer. The gate dielectric layer was deposited at a temperature of about 340 degrees Celsius and the active layer was deposited at a temperature of about 350 degrees Celsius. For substrate 2, a Corning glass substrate was used without any adhesion or barrier layer. The gate dielectric layer was deposited at a temperature of about 340 degrees Celsius and the active layer was deposited at a temperature of about 350 degrees Celsius. As shown in Table VI, the results of the two substrates are very comparable.

TABLE II

| Sub- | Mobility | | | | | S |
|---|---|---|---|---|---|---|
| strate | (cm²/VS) | Vth (V) | I_{off} (A) | Iₒₙ (A) | Iₒₙ/I_{off} | (V/dec) |
| 1 | 0.43 | 1.4 | 1.60E−12 | 4.80E−06 | 3.10E+06 | 0.82 |
| 2 | 0.49 | 1 | 2.30E−12 | 4.30E−06 | 2.20E+06 | 0.87 |

To appreciate the effects of utilizing an adhesion layer, consider Table III and the following examples.

TABLE III

| | | Adhesion layer | Barrier layer | Temperature | Film | Temperature |
|---|---|---|---|---|---|---|
| | Substrate | (Angstroms) | (Angstroms) | (Celsius) | Stack | (Celsius) |
| Comparison | Corning | N/A | N/A | N/A | g-SiN/ | 200 |
| Example 1 | non-alkali | | | | a-Si | |
| | glass | | | | | |
| Comparison | Soda lime | N/A | 9000 | 200 | g-SiN/ | 200 |
| Example 2 | glass | | | | a-Si | |
| Example 1 | Soda lime | 500 | 9000 | 200 | g-SiN/ | 345 |
| | glass | | | | a-Si | |

### Comparison Example 1

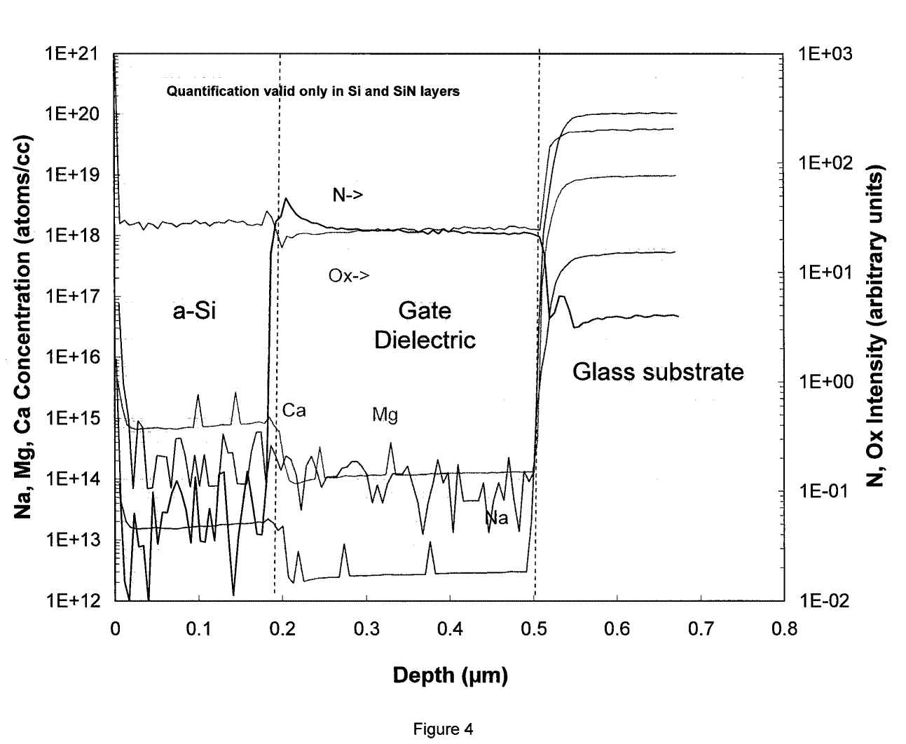

A TFT film stack in which a silicon nitride layer was used as the gate dielectric and amorphous silicon is used as the active channel was formed. The gate dielectric layer and the amorphous silicon were deposited over the Corning non-alkali glass substrate at a substrate temperature of 200 degrees Celsius. No barrier layer or adhesion layer were deposited between the substrate and the gate dielectric layer. FIG. 4 shows the results of any diffusion through the structure. As shown in FIG. 4, the sodium diffusion into the gate dielectric layer is negligible.

### Comparison Example 2

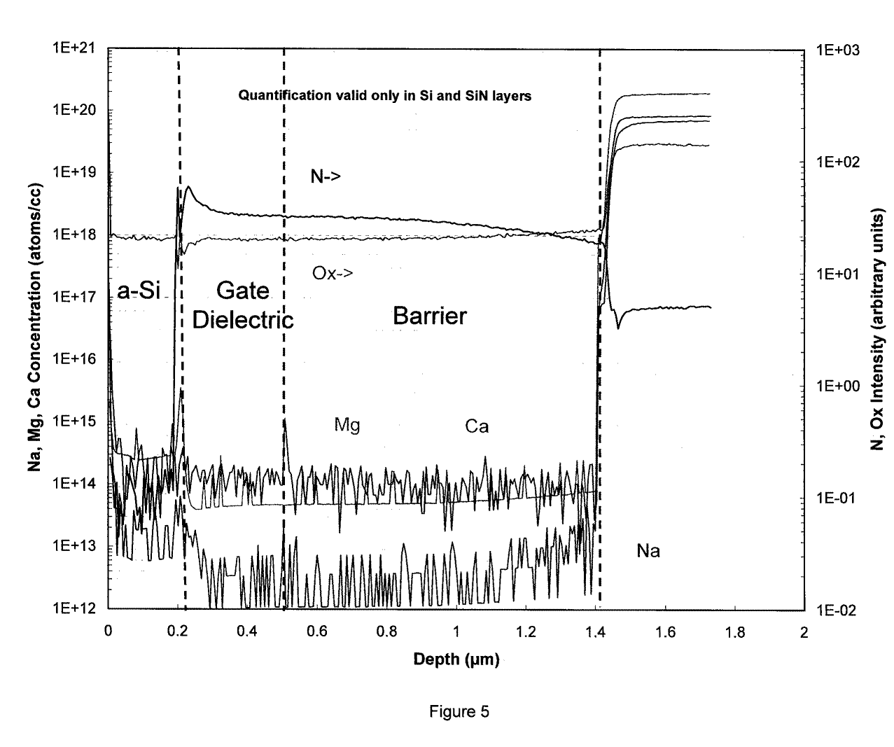

A TFT film stack was deposited over a soda lime glass substrate. A barrier layer of silicon rich, hydrogenated silicon nitride was deposited over the soda lime glass substrate at a substrate temperature of 200 degrees Celsius. The barrier layer had a thickness of 9000 Angstroms. Thereover, the film stack comprising a gate dielectric layer of silicon nitride and an active channel of amorphous silicon were deposited at a substrate temperature of 200 degrees Celsius. As shown in FIG. 5, the barrier layer effectively prevents the sodium diffusion into the gate dielectric layer. Thus, under identical conditions, a barrier layer between the soda lime glass substrate and the gate dielectric layer may permit a lower cost soda lime glass substrate to be used instead of expensive Corning non-alkali glass substrates.

Higher deposition temperatures may lead to undesired sodium diffusion. If the deposition temperature of the gate dielectric layer and the active channel were increased, the amount of sodium diffusion from the soda lime glass substrate may increase as well. At temperatures of around 200 degrees Celsius, the sodium diffusion is negligible as shown in Comparison Example 2 and FIG. 5, but at higher temperatures, the sodium may diffuse about 1500 Angstroms into the barrier layer. Additionally, the barrier layer may not adhere as well to the soda lime glass substrate at the higher temperatures and start to peel off. Therefore, the addition of an adhesion layer is beneficial.

### Example 1

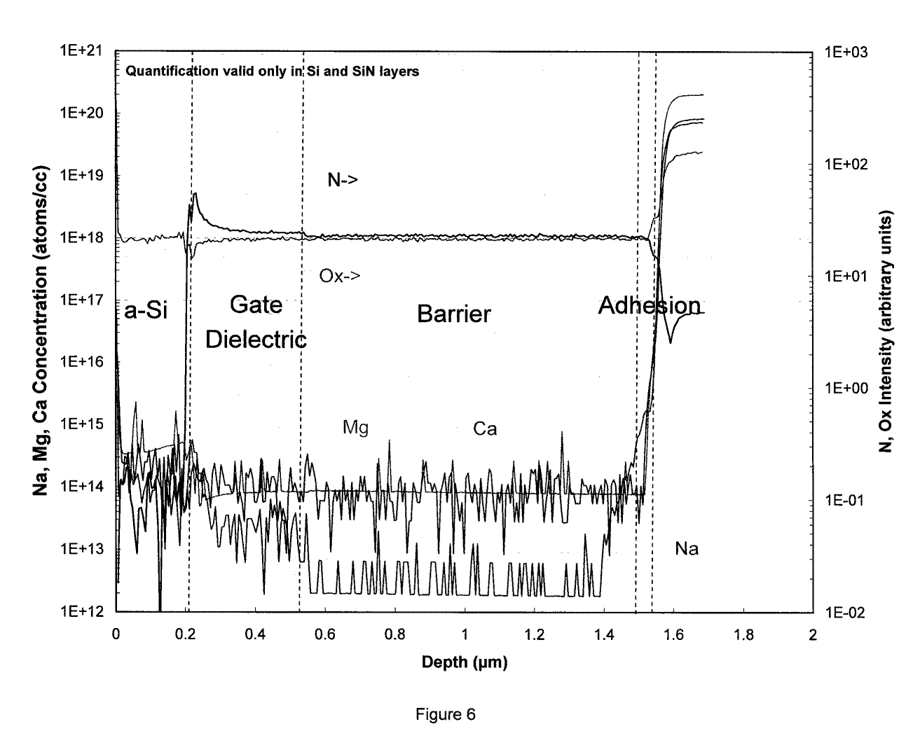

A silicon oxynitride adhesion layer having a thickness of 500 Angstroms was deposited over a soda lime glass substrate. The temperature of the substrate during the deposition was 200 degrees Celsius. Over the adhesion layer, a barrier layer of silicon rich hydrogenated silicon nitride was deposited to a thickness of 9000 Angstroms at a substrate temperature of 200 degrees Celsius. Then, a gate dielectric layer of silicon nitride and an active channel of amorphous silicon were deposited over the barrier layer at a substrate temperature of 345 degrees Celsius. As shown in FIG. 6, the sodium in the amorphous silicon layer and the gate dielectric region is comparable to that obtained with Corning non-alkali glass as shown in FIG. 4 and Comparison Example 1. Thus, by using an adhesion layer and a barrier layer, soda lime glass may be used as a substrate in TFT manufacturing. The soda lime glass substrates are beneficial because they reduce manufacturing costs.

Thus, by using an adhesion layer of silicon oxynitride between the soda lime glass substrate and the barrier layer, not only may sodium diffusion be prevented, but the barrier layer may also adhere well to the substrate even at high deposition temperatures above 300 degrees Celsius. Therefore, the adhesion layer and the barrier layer have made soda lime glass a low cost alternative to Corning glass in semiconductor device fabrication.

While the foregoing is directed to embodiments of the present invention, other and further embodiments of the invention may be devised without departing from the basic scope thereof, and the scope thereof is determined by the claims that follow.

1. A semiconductor device, comprising:
a soda lime glass substrate;
a silicon oxynitride adhesion layer disposed over the soda lime glass substrate; and
a silicon rich hydrogenated silicon nitride barrier layer disposed over the adhesion layer, the barrier layer having a SiH bond density percentage between about 15 percent to about 25 percent and a reflective index between about 1.80 and about 1.95.

2. The device of claim 1, wherein the device is a thin film transistor.

3. The device of claim 1, wherein the adhesion layer has a thickness of between about 50 Angstroms and about 2000 Angstroms.

4. The device of claim 1, wherein the barrier layer has a thickness between about 50 Angstroms and about 10000 Angstroms.

5. A semiconductor device formation method, comprising:
depositing a silicon oxynitride adhesion layer on a soda lime glass substrate; and
depositing a silicon rich silicon nitride barrier layer on the adhesion layer, the barrier layer having a SiH bond density percentage of between about 15 percent to about 25 percent and a reflective index between about 1.80 and about 1.95.

6. The method of claim 5, further comprising:
depositing a metal gate layer over the barrier layer;
depositing a gate dielectric layer over the metal gate layer;
depositing an active layer over the gate dielectric layer;
depositing a source-drain region over the active layer; and
depositing a passivation layer over the source-drain region.

7. The method of claim 6, wherein one or more of the gate dielectric layer and the active layer are deposited at a substrate temperature of greater than about 300 degrees Celsius.

8. The method of claim 5, wherein the adhesion layer is deposited by plasma enhanced chemical vapor deposition.

9. The method of claim 8, wherein the adhesion layer is deposited by introducing silane, ammonia, and nitrous oxide into a processing chamber having a gas distribution showerhead.

10. The method of claim 9, further comprising introducing nitrogen gas during the adhesion layer deposition.

11. The method of claim 9, further comprising applying RF power to the showerhead during the adhesion layer deposition.

12. The method of claim 11, wherein the RF power is between about 0.13 W/cm² to about 0.84 W/cm², the silane is delivered at a rate of between about 0.028 sccm/cm² to about 0.19 sccm/cm², the ammonia is delivered at a rate of between about 0.22 sccm/cm² to about 1.50 sccm/cm², the nitrous oxide is delivered at a rate of between about 0.13 sccm/cm² to about 0.84 sccm/cm², a process pressure is between about 500 mTorr to about 3000 mTorr, and the deposition temperature is between about 60 degrees Celsius to about 250 degrees Celsius.

13. The method of claim 5, wherein barrier layer is deposited by plasma enhanced chemical vapor deposition.

14. A thin film transistor formation method, comprising:
depositing an adhesion layer on a soda lime glass substrate;
depositing a silicon rich silicon nitride barrier layer over the adhesion layer, the barrier layer having a SiH bond density percentage between about 15 percent to about 25 percent and a reflective index between about 1.80 and about 1.95;
depositing a metal gate layer over the barrier layer;
depositing a gate dielectric layer over the metal gate layer;
depositing an active layer over the gate dielectric layer;
depositing a source-drain region over the active layer; and
depositing a passivation layer over the source-drain region.

15. The method of claim 14, wherein the adhesion layer is deposited by plasma enhanced chemical vapor deposition.

16. The method of claim 15, wherein the adhesion layer comprises silicon oxynitride.

17. The method of claim 16, wherein the adhesion layer has a thickness of between about 50 angstroms to about 2000 Angstroms.

18. The method of claim 17, wherein the barrier layer is deposited by plasma enhanced chemical vapor deposition.

19. The method of claim 14, wherein the adhesion layer is deposited at a substrate temperature of between about 60 degrees Celsius and about 250 degrees Celsius.

20. The method of claim 14, wherein the active layer is deposited at a substrate temperature of greater than about 300 degrees Celsius.
